(19) United States
(12) Patent Application Publication
(10) Pub. No.: US 2024/0320381 A1
(43) Pub. Date: Sep. 26, 2024

(54) Method For Generating Three-Dimensional Modeling Data

(71) Applicant: SEIKO EPSON CORPORATION, Tokyo (JP)

(72) Inventor: Manabu WATANABE, Shiojiri (JP)

(21) Appl. No.: 18/613,588

(22) Filed: Mar. 22, 2024

(30) Foreign Application Priority Data
Mar. 24, 2023 (JP) 2023-047859

(51) Int. Cl. G06F 30/10

(52) U.S. Cl. CPC G06F 30/10

(57) ABSTRACT

A method for generating three-dimensional modeling data includes: an acquiring step of acquiring a path condition predetermined according to a material type; and a data generation step of generating path data in which a movement path along which a nozzle moves while extruding a plasticized material is represented by a plurality of partial paths. The path data includes contour path data and infill path data, and the path condition includes a path length condition related to an upper limit of a length of the partial path in an infill area. The data generation step includes a first generation step of generating the contour path data, and a second generation step of generating the infill path data by dividing the infill area into a plurality of divided areas and generating the movement path in each of the divided areas according to a path pattern. In the second generation step, the infill area is divided such that the movement path satisfying the path length condition is generated in each of the divided areas.

The present application is based on, and claims priority from JP Application Serial Number 2023-047859, filed Mar. 24, 2023, the disclosure of which is hereby incorporated by reference herein in its entirety.

### BACKGROUND

### 1. Technical Field

The present disclosure relates to a method for generating three-dimensional modeling data.

### 2. Related Art

Regarding three-dimensional modeling, JP-A-2020-82668 describes that a modeling layer is modeled using a material containing fillers. As described above, by using the material containing fillers for modeling, warpage of an object can be prevented.

JP-A-2020-82668 is an example of the related art.

### SUMMARY

In the three-dimensional modeling, it is preferable to be able to use more various materials for user convenience. Therefore, there is a demand for a technique capable of preventing warpage of an object regardless of the presence or absence of fillers in the material.

According to a first aspect of the present disclosure, there is provided a method for generating three-dimensional modeling data for modeling a three-dimensional object by depositing a layer of a plasticized material. The method for generating three-dimensional modeling data includes: an acquiring step of acquiring slice data representing a shape of the three-dimensional object sliced into a plurality of layers; an acquiring step of acquiring material information on a material used for modeling the three-dimensional object; an acquiring step of acquiring, based on the material information, a path condition predetermined according to a material type; and a data generation step of generating, based on the slice data, path data in which a movement path along which a nozzle moves while extruding the plasticized material is represented by a plurality of partial paths. The path data includes contour path data for modeling a contour area including a contour of the three-dimensional object and infill path data for modeling an infill area which is an inner area of the contour area, and the path condition includes a path length condition related to an upper limit of a length of the partial path in the infill area. The data generation step includes a first generation step of generating the contour path data by generating the movement path in the contour area, and a second generation step of generating the infill path data by dividing the infill area into a plurality of divided areas and generating the movement path in each of the divided areas according to a predetermined path pattern. In the second generation step, the infill area is divided such that the movement path satisfying the path length condition is generated in each of the divided areas.

According to a second aspect of the present disclosure, there is provided an information processing apparatus for generating three-dimensional modeling data for modeling a three-dimensional object by depositing a layer of a plasticized material. The information processing apparatus includes: a first acquisition unit configured to acquire slice data representing a shape of the three-dimensional object sliced into a plurality of layers; a second acquisition unit configured to acquire material information on a material used for modeling the three-dimensional object; a third acquisition unit configured to acquire, based on the material information, a path condition predetermined according to a material type; and a data generation unit configured to generate, based on the slice data, path data in which a movement path along which a nozzle moves while extruding the plasticized material is represented by a plurality of partial paths. The path data includes contour path data for modeling a contour area including a contour of the three-dimensional object and infill path data for modeling an infill area which is an inner area of the contour area, and the path condition includes a path length condition related to an upper limit of a length of the partial path in the infill area. The data generation unit executes first generation processing of generating the contour path data by generating the movement path in the contour area, and second generation processing of generating the infill path data by dividing the infill area into a plurality of divided areas and generating the movement path in each of the divided areas according to a predetermined path pattern. In the second generation processing, the infill area is divided such that the movement path satisfying the path length condition is generated in each of the divided areas.

### BRIEF DESCRIPTION OF THE DRAWINGS

FIG. 1 is a diagram showing a schematic configuration of a three-dimensional modeling system.

FIG. 2 is a perspective view showing a schematic configuration of a lower surface side of a flat screw.

FIG. 3 is a schematic plan view showing an upper surface side of a barrel.

FIG. 4 is a diagram schematically showing a state in which a three-dimensional modeling apparatus models an object.

FIG. 5 is a diagram showing a schematic configuration of an information processing apparatus.

FIG. 6 is a flowchart of modeling processing.

FIG. 7 is a diagram showing an example of a shape of a three-dimensional object.

FIG. 8 is a diagram showing an example of a condition database.

FIG. 9 is a first diagram showing an example of a state in which an infill area is divided.

FIG. 10 is a first diagram showing an example of a state in which movement paths are generated in divided areas.

FIG. 11 is a second diagram showing an example of a state in which an infill area is divided.

FIG. 12 is a third diagram showing an example of a state in which an infill area is divided into divided areas.

FIG. 13 is a second diagram showing an example of a state in which movement paths are generated in the divided areas.

FIG. 14 is a third diagram showing an example of a state in which movement paths are generated in divided areas.

FIG. 15 is a first diagram showing an example of an infill path in another form.

FIG. 16 is a second diagram showing an example of an infill path in yet another form.

FIG. 17 is a third diagram showing an example of an infill path in still another form.

FIG. 18 is a diagram showing a state in which movement paths are generated in divided areas in another embodiment.

### DESCRIPTION OF EMBODIMENTS

### A. First Embodiment

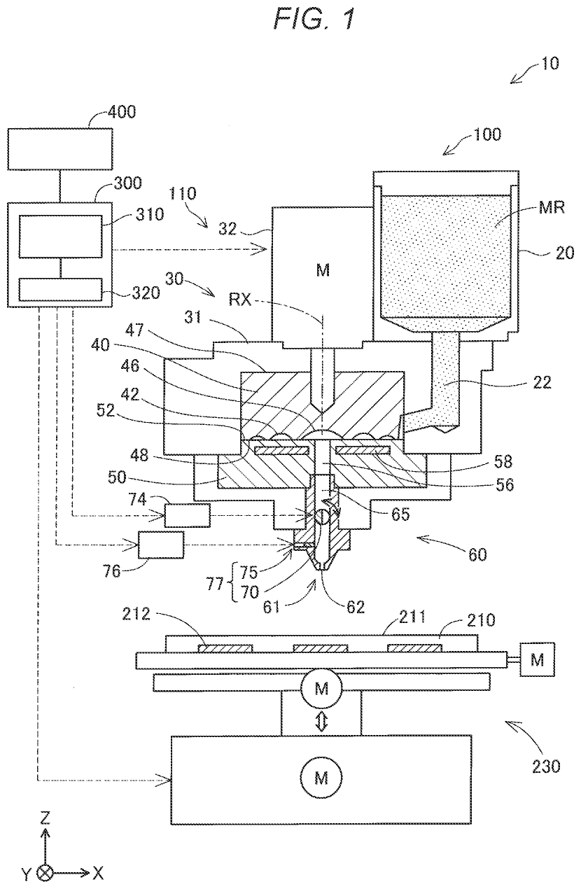

FIG. 1 is a diagram showing a schematic configuration of a three-dimensional modeling system 10 according to a first embodiment. In FIG. 1, arrows indicating X, Y, and Z directions orthogonal to one another are shown. The X direction and the Y direction are directions parallel to a horizontal plane, and the Z direction is a direction along a vertically upward direction. Arrows indicating the X, Y, and Z directions are appropriately shown in other drawings in a manner in which shown directions correspond to those in FIG. 1. In the following description, when a direction is specified, a direction indicated by an arrow in each drawing is defined as “+” and an opposite direction is defined as “−”, and positive and negative signs are used in combination in a direction notation. Hereinafter, a +Z direction is also referred to as “up”, and a-Z direction is also referred to as “down”. A plane along the X direction and the Y direction is also referred to as an “XY plane”.

The three-dimensional modeling system 10 includes a three-dimensional modeling apparatus 100 and an information processing apparatus 400. The three-dimensional modeling apparatus 100 is an apparatus that models a three-dimensional object by a material extrusion method. Hereinafter, the three-dimensional object is also simply referred to as an object. The three-dimensional modeling apparatus 100 includes a control unit 300 for controlling units of the three-dimensional modeling apparatus 100. The control unit 300 and the information processing apparatus 400 are communicably connected to each other.

The three-dimensional modeling apparatus 100 includes a modeling unit 110 that generates and extrudes a plasticized material, a modeling stage 210 serving as a base of an object, and a moving mechanism 230 that controls an extruding position of the plasticized material.

The modeling unit 110 extrudes a plasticized material obtained by plasticizing a material in a solid state onto the stage 210 under the control of the control unit 300. The modeling unit 110 includes a material supply unit 20 that is a supply source of a raw material before being converted a into the plasticized material, plasticizing unit 30 that converts the raw material into the plasticized material, and an extruding unit 60 that extrudes the plasticized material.

The material supply unit 20 supplies a raw material MR to the plasticizing unit 30. The material supply unit 20 is implemented by, for example, a hopper that accommodates the raw material MR. The material supply unit 20 is coupled to the plasticizing unit 30 via a communication path 22. The raw material MR is put into the material supply unit 20 in a form of pellets, powder, or the like. In the embodiment, a resin material formed in pellets is used.

The plasticizing unit 30 plasticizes the raw material MR supplied from the material supply unit 20 to generate a paste-shaped plasticized material exhibiting fluidity, and guides the plasticized material to the extruding unit 60. In the embodiment, the term “plasticize” is a concept including melting, and is to change from a solid state to a fluid state. Specifically, in a case of a material in which glass transition occurs, the term “plasticize” refers to setting a temperature of the material to a temperature equal to or higher than a glass transition point. In a case of a material in which the glass transition does not occur, the term “plasticize” refers to setting the temperature of the material to a temperature equal to or higher than a melting point.

The plasticizing unit 30 includes a screw case 31, a drive motor 32, a flat screw 40, and a barrel 50. The flat screw 40 is also called a rotor or a scroll. The barrel 50 is also referred to as a screw facing portion.

The flat screw 40 is accommodated in the screw case 31. An upper surface 47 of the flat screw 40 is coupled to the drive motor 32, and the flat screw 40 is rotated in the screw case 31 by a rotational drive force generated by the drive motor 32. The drive motor 32 is driven under the control of the control unit 300. The flat screw 40 may be driven by the drive motor 32 via a speed reducer.

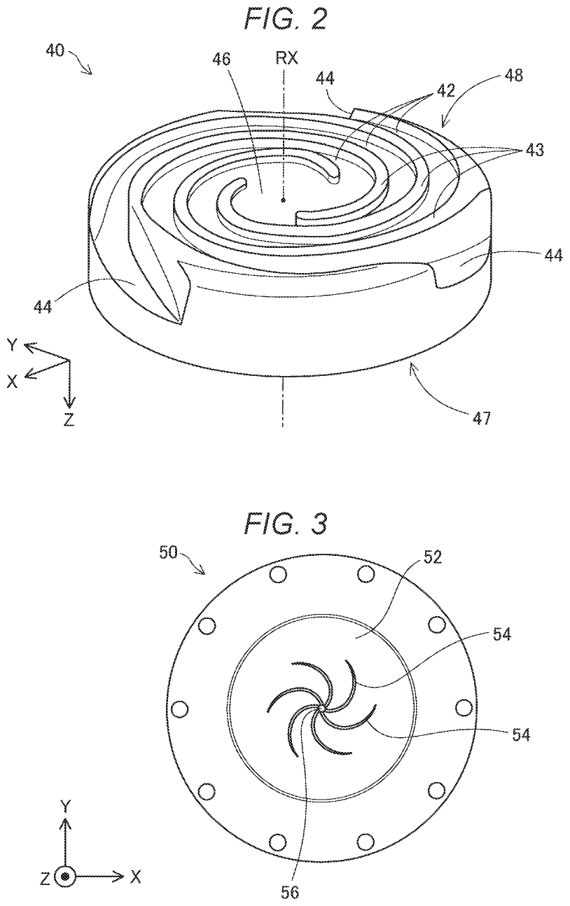

FIG. 2 is a perspective view showing a schematic configuration of a lower surface 48 of the flat screw 40. The flat screw 40 shown in FIG. 2 is shown in a state in which a positional relationship between the upper surface 47 and the lower surface 48 shown in FIG. 1 is reversed in a vertical direction. The flat screw 40 has a substantially cylindrical shape in which a length in an axial direction which is a direction along a central axis of the flat screw 40 is smaller than a length in a direction perpendicular to the axial direction. The flat screw 40 is disposed such that a rotation axis RX serving as a rotation center of the flat screw 40 is parallel to the Z direction.

Groove portions 42 in a vortex shape are formed in the lower surface 48 of the flat screw 40 which is a surface intersecting the rotation axis RX. The above-described communication path 22 of the material supply unit 20 communicates with the groove portions 42 from a side surface of the flat screw 40. In the embodiment, three groove portions 42 are formed in a manner of being separated by ridge portions 43. The number of the groove portions 42 is not limited to three, and may be one or two or more. A shape of the groove portion 42 is not limited to a vortex shape, and may have a spiral shape or an involute curve shape, or may have a shape extending in an arc from a central portion toward an outer periphery.

As shown in FIG. 1, the lower surface 48 of the flat screw 40 faces an upper surface 52 of the barrel 50, and a space is formed between the groove portions 42 of the lower surface 48 of the flat screw 40 and the upper surface 52 of the barrel 50. The raw material MR is supplied from the material supply unit 20 to the space between the flat screw 40 and the barrel 50 through material inlets 44 shown in FIG. 2.

A barrel heater 58 for heating the raw material MR supplied into the groove portions 42 of the rotating flat screw 40 is embedded in the barrel 50. A communication hole 56 is provided at the center of the barrel 50.

FIG. 3 is a schematic plan view showing the upper surface 52 of the barrel 50. A plurality of guide grooves 54 coupled to the communication hole 56 and extending in a vortex shape from the communication hole 56 toward an outer periphery are formed in the upper surface 52 of the barrel 50. One end of the guide groove 54 may not be coupled to the communication hole 56. The guide groove 54 may be omitted.

The raw material MR supplied into the groove portions 42 of the flat screw 40 flows along the groove portions 42 by the rotation of the flat screw 40 while being plasticized in the groove portions 42, and the raw material MR is guided to a central portion 46 of the flat screw 40 as a plasticized material. The paste-shaped plasticized material that exhibits fluidity and flows into the central portion 46 is supplied to the extruding unit 60 through the communication hole 56 provided at the center of the barrel 50. In the plasticized material, not all kinds of substances constituting the plasticized material may be plasticized. The plasticized material may be converted into a state having fluidity as a whole by plasticizing at least a part of substances constituting the plasticized material.

As shown in FIG. 1, the extruding unit 60 includes a nozzle 61 through which the plasticized material is extruded, a plasticized material flow path 65 provided between the flat screw 40 and a nozzle opening 62, and an extruding control unit 77 that controls extruding of the plasticized material.

The nozzle 61 is coupled to the communication hole 56 of the barrel 50 through the flow path 65. Through the nozzle 61, the plasticized material generated in the plasticizing unit 30 is extruded from the nozzle opening 62 at a tip end of the nozzle 61 toward the stage 210.

The extruding control unit 77 includes an extruding adjustment unit 70 that opens and closes the flow path 65, and a suction unit 75 that suctions and temporarily stores the plasticized material.

The extruding adjustment unit 70 is provided in the flow path 65, and changes an opening degree of the flow path 65 by being rotated in the flow path 65. In the embodiment, the extruding adjustment unit 70 is implemented by a butterfly valve. The extruding adjustment unit 70 is driven by a first drive unit 74 under the control of the control unit 300. The first drive unit 74 is implemented by, for example, a stepping motor. The control unit 300 can adjust a flow rate of the plasticized material flowing from the plasticizing unit 30 to the nozzle 61, that is, an extruding amount of the plasticized material extruded from the nozzle 61, by controlling a rotation angle of the butterfly valve using the first drive unit 74. The extruding adjustment unit 70 can adjust the extruding amount of the plasticized material and can control ON and OFF of an outflow of the plasticized material.

The suction unit 75 is coupled between the extruding adjustment unit 70 and the nozzle opening 62 in the flow path 65. The suction unit 75 temporarily suctions the plasticized material in the flow path 65 when extruding of the plasticized material from the nozzle 61 is stopped, thereby preventing a tailing phenomenon in which the plasticized material drips down from the nozzle opening 62 like a string. In the embodiment, the suction unit 75 is implemented by a plunger. The suction unit 75 is driven by a second drive unit 76 under the control of the control unit 300. The second drive unit 76 is implemented by, for example, a stepping motor, a rack-and-pinion mechanism that converts a rotation force of the stepping motor into a translational motion of a plunger, and the like.

The stage 210 is disposed at a position facing the nozzle opening 62 of the nozzle 61. In the embodiment, a modeling surface 211 of the stage 210 facing the nozzle opening 62 of the nozzle 61 is disposed in parallel to the X and Y directions, that is, a horizontal direction. The stage 210 is provided with a stage heater 212 for preventing rapid cooling of the plasticized material extruded onto the stage 210. The stage heater 212 is controlled by the control unit 300.

The moving mechanism 230 changes a relative position between the stage 210 and the nozzle 61 under the control of the control unit 300. In the embodiment, a position of the nozzle 61 is fixed, and the moving mechanism 230 moves the stage 210. The moving mechanism 230 is implemented by a three-axis positioner that moves the stage 210 in three axial directions of X, Y, and Z directions by drive forces of three motors. In the present description, unless otherwise specified, a movement of the nozzle 61 refers to relative moving the nozzle 61 or the extruding unit 60 relative to the stage 210.

In another embodiment, a configuration in which the moving mechanism 230 moves the nozzle 61 relative to the stage 210 in a state in which a position of the stage 210 is fixed may be adopted instead of a configuration in which the stage 210 is moved by the moving mechanism 230. Further, a configuration in which the stage 210 is moved in the Z direction by the moving mechanism 230 and the nozzle 61 is moved in the X and Y directions or a configuration in which the stage 210 is moved in the X and Y directions by the moving mechanism 230 and the nozzle 61 is moved in the Z direction may be adopted. With such configurations, a relative positional relationship between the nozzle 61 and the stage 210 can also be changed.

The control unit 300 is a control device that controls an overall operation of the three-dimensional modeling apparatus 100. The control unit 300 is implemented by a computer including one or more processors 310, a storage device 320 including a main storage device and an auxiliary storage device, and an input and output interface that inputs and outputs a signal to and from the outside. The processor 310 executes a program stored in the storage device 320, thereby controlling the modeling unit 110 and the moving mechanism 230 according to the modeling data acquired from the information processing apparatus 400 to model an object on the stage 210. The control unit 300 may be implemented by a combination of circuits instead of being implemented by a computer.

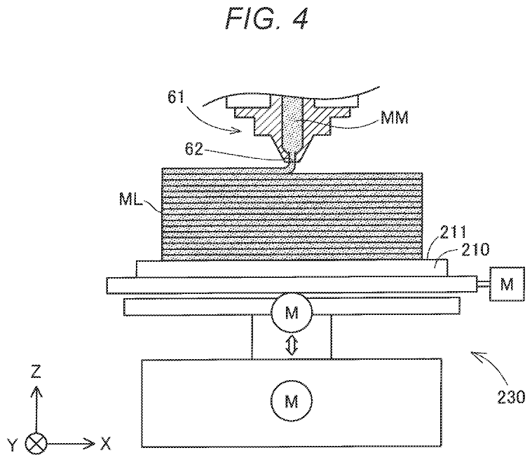

FIG. 4 is a diagram schematically showing a state in which the three-dimensional modeling apparatus 100 models an object. As described above, the raw material MR in a solid state is plasticized to generate a plasticized material MM in the three-dimensional modeling apparatus 100. The control unit 300 causes the nozzle 61 to extrude the plasticized material MM while changing a position of the nozzle 61 relative to the stage 210 in a direction along the modeling surface 211 of the stage 210 and maintaining a distance between the modeling surface 211 of the stage 210 and the nozzle 61. The plasticized material MM extruded from the nozzle 61 is continuously deposited in a moving direction of the nozzle 61.

The control unit 300 forms layers ML by repeating a movement of the nozzle 61. After forming one layer ML, the control unit 300 moves a position of the nozzle 61 relative to the stage 210 in the Z direction. Then, the layer ML is further deposited on layers ML that are formed so far, thereby modeling an object.

For example, the control unit 300 may temporarily interrupt a movement of the nozzle 61 in the Z direction when the layer ML for one layer is completed, or temporarily interrupt extruding of the plasticized material from the nozzle 61 when there are a plurality of independent modeling areas in each layer. In this case, the flow path 65 is closed by the extruding adjustment unit 70, extruding of the plasticized material MM from the nozzle opening 62 is stopped, and the plasticized material in the nozzle 61 is temporarily suctioned by the suction unit 75. After the control unit 300 changes a position of the nozzle 61, the extruding adjustment unit 70 opens the flow path 65 while discharging the plasticized material in the suction unit 75, thereby restarting depositing of the plasticized material MM from a changed position of the nozzle 61.

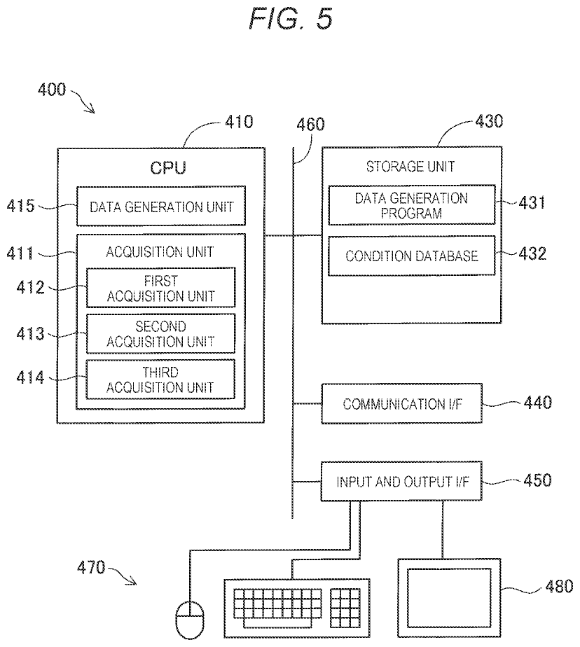

FIG. 5 is a diagram showing a schematic configuration of the information processing apparatus 400. The information processing apparatus 400 is implemented as a computer in which a CPU 410, a storage unit 430, a communication interface 440, and an input and output interface 450 are mutually connected by a bus 460. An input device 470 such as a keyboard and a mouse and a display device 480 such as a liquid crystal display are connected to the input and output interface 450. The information processing apparatus 400 is connected to the control unit 300 of the three-dimensional modeling apparatus 100 via the communication interface 440. In the embodiment, the storage unit 430 stores a data generation program 431 and a condition database 432, which will be described later.

The CPU 410 executes the data generation program 431 stored in the storage unit 430 to cause the information processing apparatus 400 to implement functions of an acquisition unit 411 and a data generation unit 415. As described later, the data generation unit 415 generates three-dimensional modeling data to be described later. The acquisition unit 411 acquires various types of information used to generate the three-dimensional modeling data. The acquisition unit 411 includes a first acquisition unit 412, a second acquisition unit 413, and a third acquisition unit 414.

The first acquisition unit 412 acquires slice data. The slice data is data representing a shape of a three-dimensional object sliced into a plurality of layers. The slice data is generated by slicing the shape of the three-dimensional object into a plurality of layers along the XY plane based on shape data representing the shape of the three-dimensional object, for example. The shape data is, for example, three-dimensional shape data created using three-dimensional CAD software, three-dimensional CG software, or the like, and is data in an STL format, an AMF format, or the like.

The second acquisition unit 413 acquires material information. The material information is information on a material used for modeling a three-dimensional object desired to be modeled. The material information may be associated with, for example, the shape data. For example, the above-described shape data or slice data may include identification information for designating a material for modeling a three-dimensional object represented by the shape data. In this case, the second acquisition unit 413 may acquire the identification information as the material information.

The third acquisition unit 414 acquires a path condition based on the material information acquired by the second acquisition unit 413. The path condition is a condition related to a movement path to be described later, and is determined in advance according to a material type. Details of the path condition will be described later.

The data generation unit 415 generates three-dimensional modeling data based on the slice data and the path condition. Hereinafter, the three-dimensional modeling data is also simply referred to as modeling data. The modeling data includes path data and extruding amount information associated with the path data. The path data is data in which a movement path, which is a path along which the nozzle 61 moves while extruding the plasticized material, is represented by a plurality of partial paths. The partial path is a linear path, and is represented using, for example, a start point and an end point of the partial path. The extruding amount information is information indicating an extruding amount of the plasticized material in each partial path.

The path data includes contour path data and infill path data. The contour path data is data representing a movement path for modeling a contour area of the three-dimensional object. The contour area refers to an area including a contour of the three-dimensional object. The infill path data is data representing a movement path for modeling an infill area of the three-dimensional object. The infill area refers to an inner area of the contour area. Hereinafter, the movement path for modeling the contour area is also referred to as a contour path, and the movement path for modeling the infill area is also referred to as an infill path.

The above-described path condition includes various conditions related to the infill path. The condition related to the infill path includes a path length condition. The path length condition is a condition related to an upper limit of a length of the partial path in the infill area.

The information processing apparatus 400 transmits the modeling data generated by the data generation unit 415 to the control unit 300 of the three-dimensional modeling apparatus 100. The control unit 300 controls the extruding unit 60 and the moving mechanism 230 according to the received modeling data to extrude the plasticized material onto the stage 210, and deposits a layer of the plasticized material in a depositing direction while solidifying the plasticized material on the stage 210, thereby modeling an object. In the embodiment, the depositing direction is the Z direction. The solidification of the plasticized material means that the extruded plasticized material loses fluidity. When a temperature of the plasticized material decreases, the plasticized material thermally contracts and loses plasticity to be solidified. Hereinafter, the layer of the plasticized material deposited by the extruding unit 60 and the moving mechanism 230 is also referred to as a modeling layer.

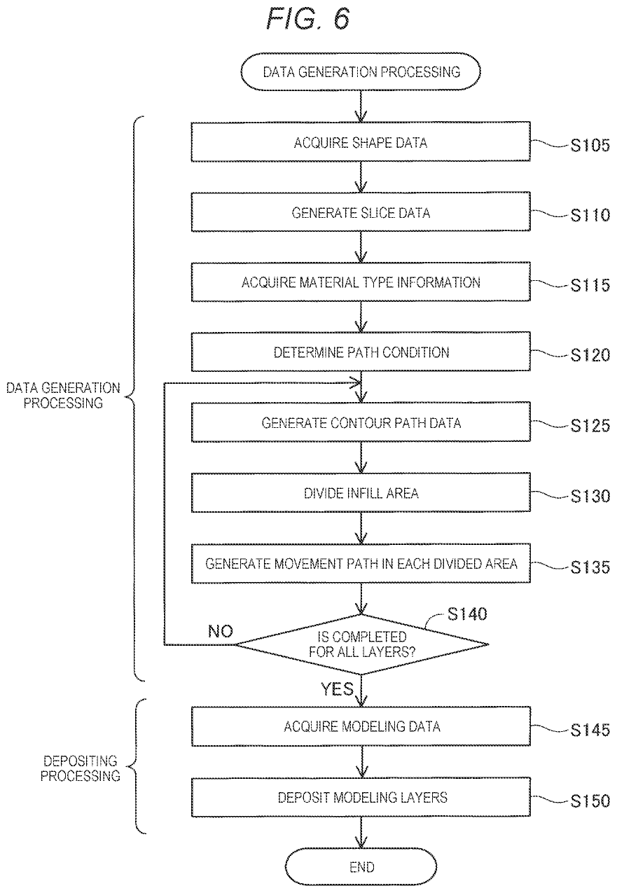

FIG. 6 is a flowchart of modeling processing executed in the three-dimensional modeling system 10. The modeling processing in the embodiment includes data generation processing and depositing processing. The data generation processing is processing for generating the modeling data, and implements the method for generating modeling data in the embodiment. The depositing processing is processing of depositing a modeling layer by the extruding unit 60 and the moving mechanism 230. The modeling processing shown in FIG. 6 is executed, for example, when a predetermined start operation is performed by a user on the control unit 300. The processing in steps S105 to S140 is executed in the information processing apparatus 400, and the processing in steps S145 and S150 is executed in the three-dimensional modeling apparatus 100.

In step S105, the acquisition unit 411 acquires shape data from another computer, a recording medium, or the storage unit 430. In step S110, the first acquisition unit 412 acquires slice data. The first acquisition unit 412 in the embodiment acquires the slice data by generating the slice data based on the shape data acquired in step S105.

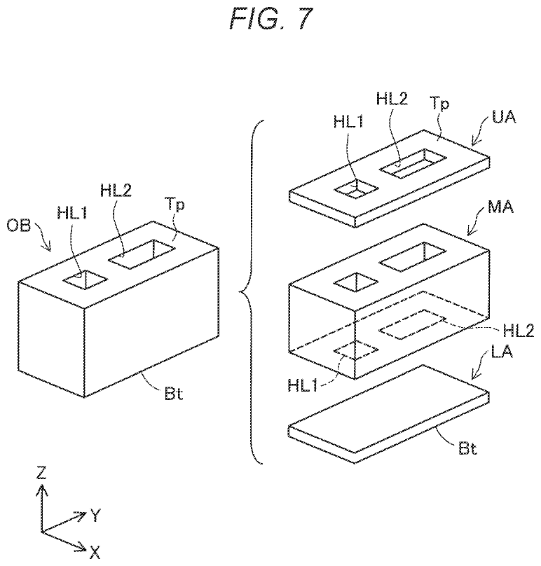

FIG. 7 is a diagram showing an example of a shape of a three-dimensional object OB represented by the shape data and the slice data. The three-dimensional object OB includes a lower layer area LA, an upper layer area UA, and a middle layer area MA. The lower layer area LA is an area including a lowermost layer Bt of the three-dimensional object OB. The lower layer area LA may be formed of only the lowermost layer Bt, or may be formed of a plurality of layers that include the lowermost layer Bt and are continuous in the depositing direction. In the embodiment, the lower layer area LA is formed of five consecutive layers including the lowermost layer Bt. The upper layer area UA is an area including an uppermost layer Tp of the three-dimensional object OB. The upper layer area UA may be formed of only the uppermost layer Tp, or may be formed of a plurality of layers that include the uppermost layer Tp and are continuous in the depositing direction. In the embodiment, the upper layer area UA is formed of only the uppermost layer Tp. The middle layer area MA is an area between the upper layer area UA and the lower layer area LA. The middle layer area MA may be formed of only one layer, or may be formed of a plurality of layers continuous in the depositing direction. As described later, the middle layer area MA is modeled at a density lower than that of the upper layer area UA and the lower layer area LA. By increasing the number of layers constituting the upper layer area UA and the lower layer area LA, the upper layer area UA and the lower layer area LA can be modeled with higher strength. From the viewpoint of shortening a modeling time, the number of layers in the upper layer area UA and the lower layer area LA is preferably 5 or less, for example.

The above-described path data includes lower layer data for modeling the lower layer area LA, upper layer data for modeling the upper layer area UA, and middle layer data for modeling the middle layer area MA. The lower layer data, the upper layer data, and the middle layer data respectively include contour path data and infill path data.

The three-dimensional object OB shown in FIG. 7 has a rectangular parallelepiped shape as a whole. A first hole HL1 and a second hole HL2 each extending in the depositing direction are formed in the three-dimensional object OB. The first hole HL1 and the second hole HL2 are open upward in the uppermost layer Tp and extend downward from the uppermost layer Tp to a lower end of the middle layer area MA. Accordingly, in the example in FIG. 7, the first hole HL1 and the second hole HL2 are partially formed in the upper layer area UA and the middle layer area MA, respectively, and the first hole HL1 and the second hole HL2 are not formed in the lower layer area LA.

In step S115 in FIG. 6, the second acquisition unit 413 acquires the material information. In step S115 in the embodiment, the second acquisition unit 413 acquires the material information associated with the shape data acquired in step S105.

In step S120, the third acquisition unit 414 acquires the path condition based on the material information acquired in step S115. In step S120 in the embodiment, the third acquisition unit 414 acquires, based on the material information, the path condition including the path length condition by referring to the condition database 432 stored in the storage unit 430.

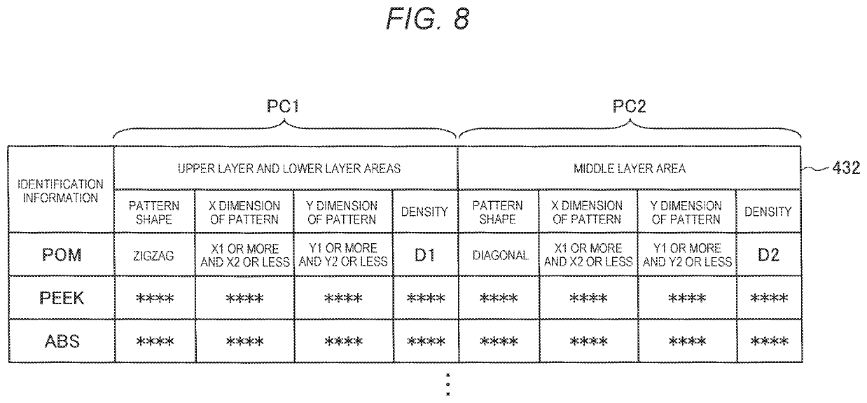

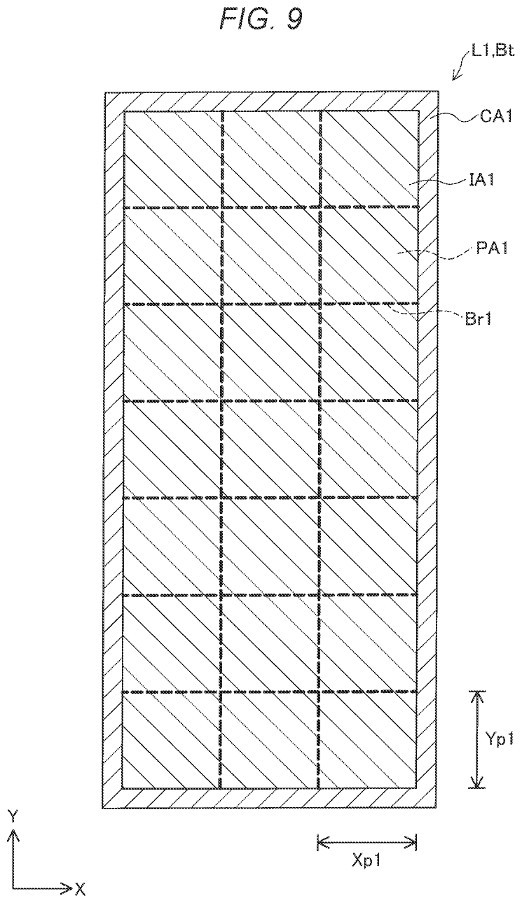

FIG. 8 is a diagram showing an example of the condition database 432. In the condition database 432, type information representing a material type and the path condition are stored in association with each other.

As shown in FIG. 8, in the condition database 432 in the embodiment, a first path condition PC1 related to the infill path in the upper layer area UA and the lower layer area LA and a second path condition PC2 related to the infill path in the middle layer area MA are defined as the path condition for each material type. The path condition in the embodiment includes a pattern shape condition for determining a shape type of the path pattern, an X dimension condition for determining an X dimension of the pattern, a Y dimension condition for determining a Y dimension of the pattern, and a density condition for determining a modeling density in the infill area. The modeling density is defined as a proportion of an area occupied by the plasticized material extruded along the movement path in the infill area.

For example, in the condition database 432, the first path condition PC1 when the material type is POM is defined as a condition for generating a zigzag path, which is a zigzag movement path, with a dimension X1 or more and a dimension X2 or less in the X direction, a dimension Y1 or more and a dimension Y2 or less in the Y direction, and at a modeling density of a density range D1. Similarly, the second path condition PC2 when the material type is POM is defined as a condition for generating a diagonal path, which is a diagonal pattern movement path, with the dimension X1 or more and the dimension X2 or less in the X direction, the dimension Y1 or more and the dimension Y2 or less in the Y direction, and at a modeling density of a density range D2. The density range D2 is a density range with a value smaller than that of the density range D1. Details of the zigzag path and the diagonal path will be described later. As described later, the X dimension condition and the Y dimension condition are conditions for determining a maximum path length of the partial path, and correspond to the above-described path length condition.

The path length condition related to a material of a certain type is determined, for example, as a condition under which warpage of a three-dimensional object can be prevented when the three-dimensional object is modeled using the material of the certain type. The warpage of the three-dimensional object is generally caused by thermal contraction during solidification of the plasticized material. Therefore, the path length condition may be determined, for example, based on a result of measuring a thermal contraction amount when a material of each type is cooled from a plasticization temperature to a temperature at solidification by experiment or simulation. Generally, the warpage of the three-dimensional object is more likely to occur as the plasticization temperature of the material is higher. This is because a temperature difference between when the material is plasticized and when the material is solidified increases, and the thermal contraction amount at solidification of the material increases. For example, the warpage of the three-dimensional object is more likely to occur as a thermal expansion coefficient of the material is larger. Therefore, the path length condition may be determined based on, for example, the plasticization temperature or the thermal expansion coefficient of the material. In this case, for example, the path length condition may also be determined in such a manner that the greater the plasticization temperature of the material, the shorter the maximum path length of the partial path. In determining the plasticization temperature, for a material in which glass transition occurs, the plasticization temperature thereof may be determined to be higher as the glass transition point of the material is higher. For a material in which the glass transition does not occur, the plasticization temperature thereof may be determined to be higher as the melting point of the material is higher.

In step S125, the data generation unit 415 generates the contour path data based on the slice data acquired in step S110. More specifically, the data generation unit 415 generates the contour path data by generating contour paths of a predetermined number of cycles in the contour area. The number of cycles may be one, or may be two or more. In the embodiment, the data generation unit 415 generates a contour path for one round in the contour area in step S125. The step of generating the contour path data as in step S125 is also referred to as a first generation step. The processing of executing the first generation step is also referred to as first generation processing.

In step S130, the data generation unit 415 divides the infill area into a plurality of divided areas based on the slice data acquired in step S110 and the path condition determined in step S120. In step S130, the data generation unit 415 divides the infill area into a plurality of divided areas such that a movement path satisfying the path length condition is generated in each of the divided areas in the next step S135. In step S135, the data generation unit 415 generates an infill path by generating the movement path in each of the divided areas generated in step S130 according to a predetermined path pattern. In the embodiment, in step S135, the data generation unit 415 generates the movement path for each of the divided areas according to the path pattern determined by a pattern condition included in the path condition. The step of dividing the infill area into a plurality of divided areas and generating the movement path in each of the divided areas according to the path pattern to generate the infill path data, as in steps S130 and S135, is also referred to as a second generation step. The processing of executing the second generation step is also referred to as second generation processing. In the second generation step, the step of dividing the infill area as in step S130 is also referred to as a first step, and the step of generating the movement path in each divided area as in step S135 is also referred to as a second step.

In the second generation step, for example, the first step and the second step may be alternately and repeatedly executed to generate the infill path. In this case, for example, after temporarily dividing the infill area in the first step, the movement path may be generated in each of the divided areas immediately before in the second step, the division may be executed again in the first step for the second time in consideration of a generation result of the movement path immediately before, and the movement path may be generated in each of the divided areas immediately before in the second step for the second time.

In step S140, the data generation unit 415 determines whether movement paths are generated for all layers. When the data generation unit 415 determines in step S140 that there is a layer for which the path data is not generated, the processing returns to step S125. When the data generation unit 415 determines in step S140 that the movement paths are generated for all layers, generation of the path data is completed. The step of generating the path data based on the slice data as in steps S125 to S140 is also referred to as a data generation step. That is, the data generation step includes the first generation step and the second generation step. As described above, the extruding amount information is associated with the path data generated by the data generation step. Thereafter, in step S145, the control unit 300 of the three-dimensional modeling apparatus 100 acquires the generated modeling data from the information processing apparatus 400. In step S150, the control unit 300 deposits a modeling layer according to the modeling data acquired in step S145.

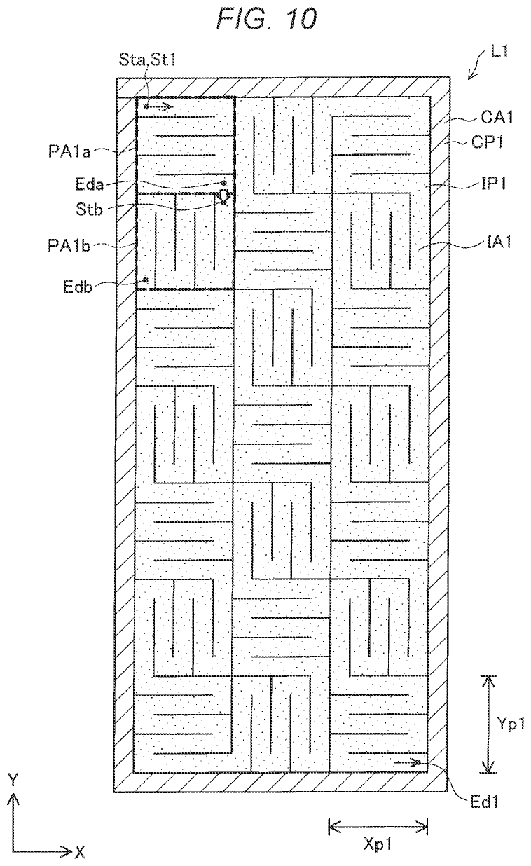

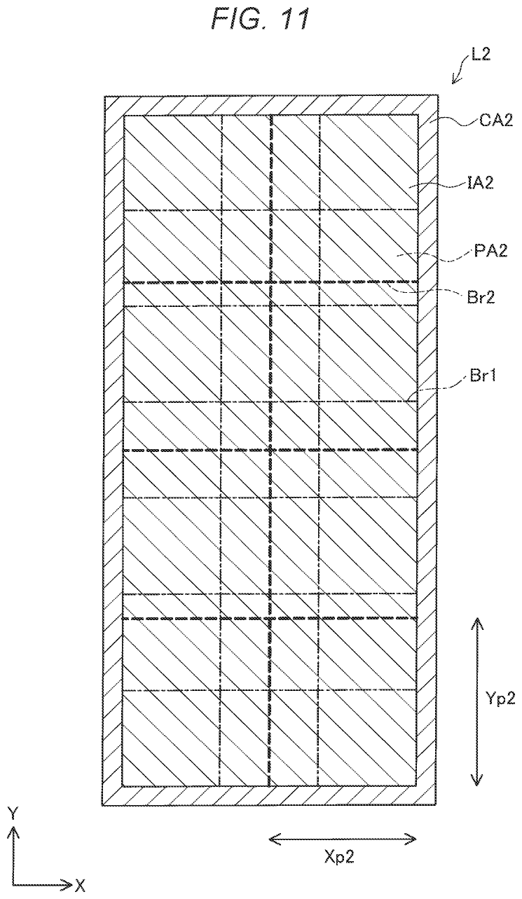

FIG. 9 is a first diagram showing an example of a state in which an infill area is divided in step S130. FIG. 10 is a first diagram showing an example of a state in which movement paths are generated in divided areas in step S135. FIG. 9 shows a state in which an infill area IA1 of a first layer L1 is divided into a plurality of divided areas PA1. FIG. 10 shows a state in which a movement path is generated in each of the divided areas PA1. The term “n-th layer” refers to the n-th layer counted from a layer closer to the stage 210 in the depositing direction. That is, the layer L1 corresponds to the above-described lowermost layer Bt. The infill area IA1 is an inner area of a contour area CA1 constituting an outer peripheral portion of the layer L1. In FIG. 9, the contour area CA1 is hatched upward to the right, and the infill area IA1 is hatched downward to the right. In FIG. 10, a contour path CP1 generated in the contour area CAL is hatched upward to the right, and the movement path generated in the infill area IA1 is hatched in a dotted pattern.

In the embodiment, in step S130, the data generation unit 415 divides the infill area IA1 into the plurality of divided areas PA1 according to at least the following division condition. That is, the division condition is that each of the divided areas PA1 has a rectangular shape with the same area, that the X dimension of each of the divided areas PA1 satisfies the X dimension condition, that the Y dimension of each of the divided areas PA1 satisfies the Y dimension condition, and that the movement path of the path pattern according to the pattern condition can be generated in each of the divided areas PA1. As a result, in the example in FIG. 9, the infill area IA1 is divided into 21 divided areas PA1. In FIG. 9, a division boundary Br1 which is a boundary between the divided areas PA1 is indicated by a broken line. A dimension Xp1 of the divided area PAL in the X direction is the dimension X1 or more and the dimension X2 or less, and a dimension Yp1 of the divided area PA1 in the Y direction is the dimension Y1 or more and the dimension Y2 or less. In the embodiment, the infill areas of a third layer and a fifth layer are also each divided in the same manner as in FIG. 9. That is, in the embodiment, the infill areas of odd-numbered layers constituting the lower layer area LA are each divided into 21 divided areas as described above. In the embodiment, the movement paths are generated in the infill area of each of the odd-numbered layers constituting the lower layer area LA in the same manner as in FIG. 10.

In the example in FIG. 10, a continuous infill path IP1 from a start point St1 to an end point Ed1 is generated in the infill area IA1 of the layer L1. The infill path IP1 is implemented by a zigzag path generated in each of the divided areas PA1. The zigzag path refers to a movement path that moves along a main direction within an area where the zigzag path is to be generated and also proceeds along a sub direction perpendicular to the main direction while folding back to the main direction. More specifically, the zigzag path includes a partial path extending from one side to the other side in the main direction and a partial path extending from the other side to the one side in the main direction, which are arranged alternately, and a partial path along the sub direction connecting ends of the partial paths that are arranged alternately in this way.

In the embodiment, the zigzag path is generated with one of the X direction and the Y direction as the main direction and the other as the sub direction. Hereinafter, a zigzag path with the X direction as the main direction, that is, a zigzag path that is folded back in the X direction is also referred to as a first zigzag path. The zigzag path that is folded back in the Y direction is also referred to as a second zigzag path. For example, a maximum path length of the partial path constituting the first zigzag path is determined by a dimension of the divided area where the first zigzag path is to be generated in the X direction. Therefore, as described above, when the dimension of the divided area PA1 in the X direction satisfies the X dimension condition, the maximum path length of the partial path constituting the first zigzag path generated in the divided area PA1 also satisfies the X dimension condition. Similarly, when a dimension of the divided area PAL in the Y direction satisfies the Y dimension condition, a maximum path length of the partial path constituting the second zigzag path generated in the divided area PA1 also satisfies the Y dimension condition. That is, in the embodiment, since the infill area IA1 is divided according to the X dimension condition or the Y dimension condition in step S130, the upper limit of the length of the partial path generated in the infill area IA1 in step S135 is determined as a longer dimension of the dimension X2 and the dimension Y2 shown in FIG. 8. In this way, the X dimension condition and the Y dimension condition correspond to the path length condition.

In the example in FIG. 10, the movement paths are generated such that a direction of the path pattern is different between a first divided area PA1a and a second divided area PA1b that are adjacent divided areas. More specifically, in the embodiment, a zigzag path that is folded back in a first direction is generated in the first divided area PA1a, and a zigzag path that is folded back in a second direction intersecting the first direction is generated in the second divided area PA1b. More specifically, the first zigzag path is generated in the first divided area PA1a, and the second zigzag path is generated in the second divided area PA1b. In the example in FIG. 10, the direction of the path pattern is different not only in the first divided area PA1a and the second divided area PA1b but also in adjacent divided areas.

As shown in FIG. 10, in the embodiment, in step S135, the data generation unit 415 generates a path in each of the divided areas PA such that ends of the movement paths in adjacent divided areas PA1 are coupled to each other. For example, in the example in FIG. 10, the infill path IP1 is generated such that a terminal end Eda of the movement path in the first divided area PA1a is coupled to a start end Stb of the movement path in the second divided area PA1b. In this way, during modeling, the nozzle 61 moves from a start end Sta toward the terminal end Eda while extruding the plasticized material in the first divided area PA1a, and then can move from the terminal end Eda toward a start end Stb as indicated by a white arrow while continuing extruding of the plasticized material. Therefore, for example, the modeling in the first divided area PA1a and the modeling in the second divided area PA1b can be continuously executed without stopping the extruding of the plasticized material. Similarly, a terminal end Edb of the path in the second divided area PA1b is coupled to a start end of a path in a divided area located in a-Y direction of the second divided area PA1b.

FIG. 11 is a second diagram showing an example of a state in which an infill area is divided. FIG. 11 shows a state in which an infill area IA2 inside a contour area CA2 of a second layer L2 is divided into a plurality of divided areas PA2, in substantially the same manner as in FIG. 9. In the example in FIG. 11, the infill area IA2 is divided into the plurality of divided areas PA2 according to the above-described division condition such that a division boundary Br2, which is a boundary between the divided areas PA2, and the above-described division boundary Br1 are shifted from each other when viewed along the depositing direction. As a result, the infill area IA2 is divided into 8 divided areas PA2. In FIG. 11, the division boundary Br2 is indicated by a broken line, and the division boundary Br1 is indicated by a one-dot chain line. A dimension Xp2 of the divided area PA2 in the X direction is larger than the dimension Xp1 and is the dimension X1 or more and the dimension X2 or less. A dimension Yp2 of the divided area PA2 in the Y direction is larger than the dimension Yp1, and is the dimension Y1 or more and the dimension Y2 or less. In the embodiment, a fourth layer is also divided similarly to the layer L2. That is, in the embodiment, the infill areas of even-numbered layers constituting the lower layer area LA are each divided into 8 divided areas as described above. Although not shown, the movement paths are generated in each of the even-numbered layers constituting the lower layer area LA in substantially the same manner as the layer L1.

As described above, in the embodiment, the infill areas of the first layer and the second layer are divided such that the division boundary of the first layer and the division boundary of the second layer continuous with the first layer in the depositing direction are shifted from each other. The expression “division boundaries of a certain layer and another layer are shifted from each other” means a state in which the division boundaries of both layers do not overlap with each other at least partially in an overlapping area where the infill areas of both layers overlap with each other when viewed along the depositing direction. An overlapping degree between the division boundary of the first layer and the division boundary of the second layer is preferably 50% or less. The overlapping degree Can be calculated as a proportion of a length by which a division boundary with a longer total length in the overlapping area overlaps in parallel with a division boundary with a shorter total length in the overlapping area among the division boundaries of both layers when viewed along the depositing direction. In the examples in FIGS. 9 and 11, the overlapping degree is 0%.

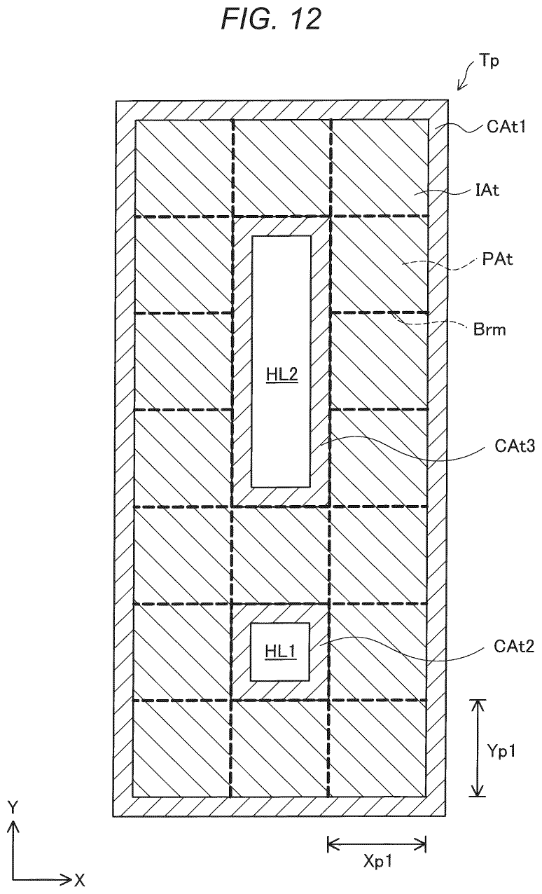

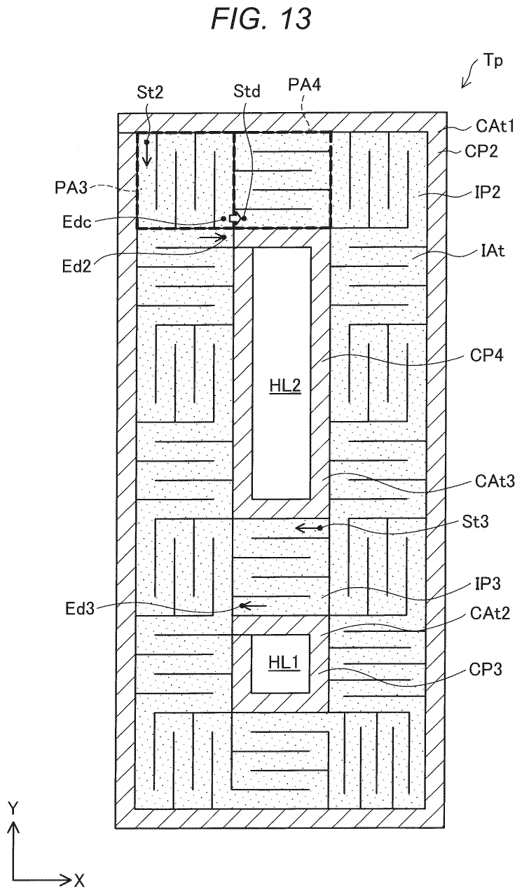

FIG. 12 is a third diagram showing an example of a state where an infill area is divided into divided areas in step S130. FIG. 13 is a second diagram showing an example of a state in which movement paths are generated in the divided areas in step S135. FIG. 12 shows a state in which an infill area IAt of the uppermost layer Tp is divided into a plurality of divided areas PAt, in substantially the same manner as in FIG. 9. FIG. 13 shows a state in which paths are generated in each of the divided areas PAt, in substantially the same manner as in FIG. 10. The infill area IAt includes inner areas of a contour area CAt1 constituting an outer peripheral portion of the uppermost layer Tp, a contour area CAt2 surrounding the periphery of the first hole HL1, and a contour area CAt3 surrounding the periphery of the second hole HL2.

In the example in FIG. 12, 17 divided areas PAt are generated as a result of dividing the infill area IAt according to the above-described division condition. In FIG. 12, a division boundary Brt which is a boundary between the divided areas PAt is indicated by a broken line. A dimension of the divided area PAt is the same as the dimension of the divided area PA1. In the embodiment, the infill area of each layer constituting the middle layer area MA is divided into 17 divided areas, in substantially the same manner as the infill area IAt shown in FIG. 12.

In the example in FIG. 13, a contour path CP2, a contour path CP3, and a contour path CP4 are generated in contour areas CAt1, CAt2, and CAt3, respectively. In the infill area IAt, an infill path IP2 from a start point St2 to an end point Ed2 and an infill path IP3 from a start point St3 to an end point Ed3 are generated. The infill path IP2 is generated in substantially the same manner as the infill path IP1 shown in FIG. 10 such that ends of the movement paths in the adjacent divided areas PAt are coupled to each other. For example, in FIG. 13, a terminal end Edc of a movement path generated in a third divided area PA3 is coupled to a start end Std of a movement path generated in a fourth divided area PA4 adjacent to the third divided area PA3. The infill path IP3 is generated in an area of the infill area IAt where the infill path IP2 is not generated. The infill path IP2 and the infill path IP3 are implemented by zigzag paths generated in each of the divided areas PAt, in substantially the same manner as the infill path IP1 shown in FIG. 10. In the example in FIG. 13, the direction of the path pattern is different in adjacent divided areas PAt, in the same manner as the example in FIG. 12.

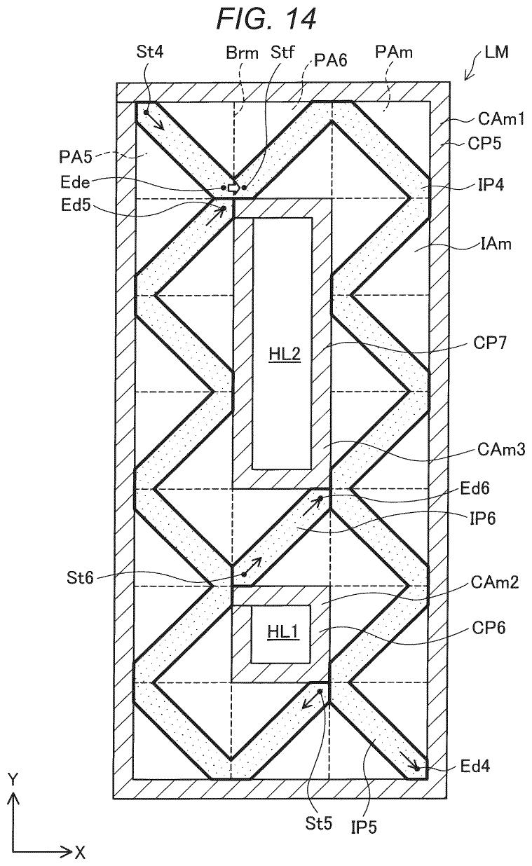

FIG. 14 is a third diagram showing an example of a state in which movement paths are generated in divided areas in step S135. FIG. 14 shows a state in which a movement path is generated in each of divided areas PAm of a layer LM constituting the middle layer area MA. In the example in FIG. 14, the divided area PAm is generated by dividing an infill area IAm of the layer LM. The infill area IAm includes inner areas of a contour area CAm1 constituting an outer peripheral portion of the layer LM, a contour area CAm2 surrounding the periphery of the first hole HL1, and a contour area CAm3 surrounding the periphery of the second hole HL2. In FIG. 14, a division boundary Brm which is a boundary between the divided areas PAm is indicated by a broken line.

In the example in FIG. 14, a contour path CP5, a contour path CP6, and a contour path CP7 are generated in the contour areas CAm1, CAm2, and CAm3, respectively. In FIG. 14, each contour path is hatched upward to the right. In the infill area IAm, an infill path IP4 from a start point St4 to an end point Ed4, an infill path IP5 from a start point St5 to an end point Ed5, and an infill path IP6 from a start point St6 to an end point Ed6 are generated. In FIG. 14, the respective infill paths are indicated by dotted hatching and thick lines. The infill path IP4 is generated in substantially the same manner as the infill path IP1 shown in FIG. 10 such that ends of the paths in the adjacent divided areas PAm are coupled to each other. For example, in the infill path IP4, a terminal end Ede of a movement path generated in a fifth divided area PA5 is coupled to a start end Stf of a movement path generated in a sixth divided area PA6 adjacent to the fifth divided area PA5. The infill path IP5 is generated such that ends of the paths in the adjacent divided areas PAm are coupled to each other in an area of the infill area IAm where the infill path IP4 is not generated. The infill path IP6 is generated in an area of the infill area IAm where the infill path IP4 and the infill path IP5 are not generated.

As shown in FIG. 14, the infill paths IP4, IP5, and IP6 are each the above-described diagonal path. The diagonal path refers to a movement path generated along a diagonal of a rectangular area where the diagonal path is to be generated. A maximum path length of the partial paths constituting the diagonal path is determined by the X dimension condition and the Y dimension condition. In the example in FIG. 14, as in FIG. 10, the direction of the path pattern is different in the adjacent divided areas PAm.

The above-described method for generating modeling data in the embodiment includes the second generation step of generating the infill path data by dividing the infill area into the plurality of divided areas and generating the movement path in each of the divided areas according to the predetermined path pattern. In the second generation step, the infill area is divided such that the movement path satisfying the path length condition is generated in each of the divided areas.

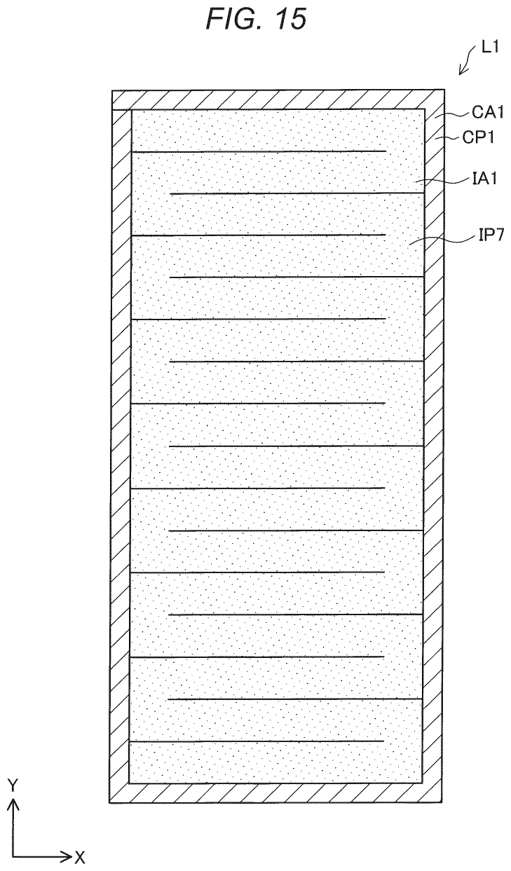

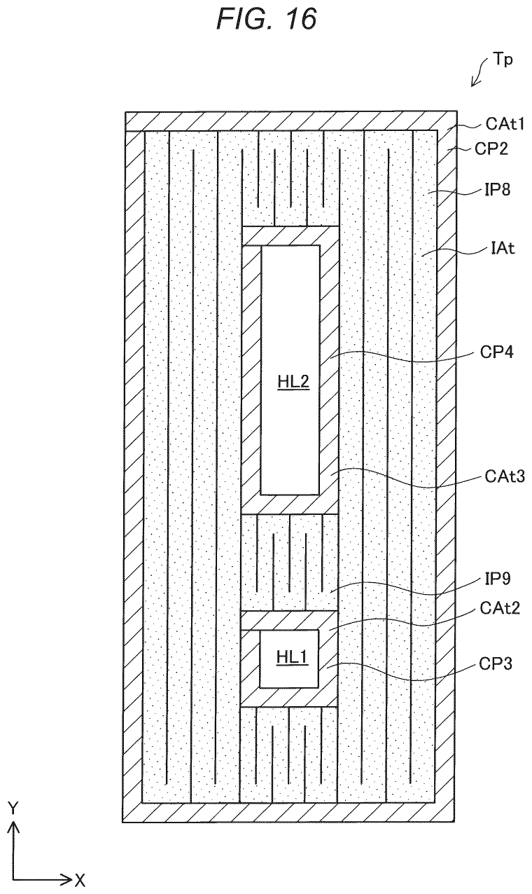

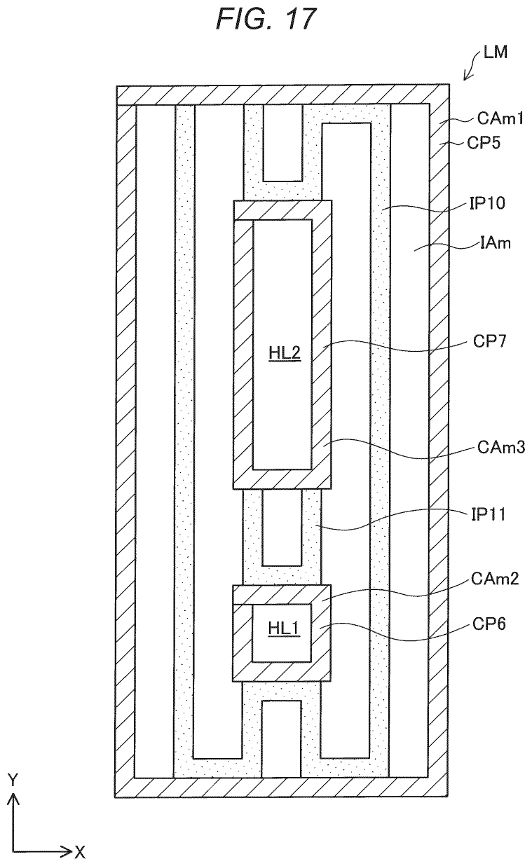

FIGS. 15 to 17 are diagrams showing examples of infill paths in other forms, respectively. FIGS. 15 to 17 show examples of a case where an infill path for generating the three-dimensional object OB as in FIG. 7 is generated without dividing the infill area unlike the embodiment, respectively. FIG. 15 shows an infill path IP7 for modeling the infill area IA1 of the first layer L1 at a modeling density comparable to that in FIG. 10. FIG. 16 shows an infill path IP8 and an infill path IP9 for modeling the infill area IAt of the uppermost layer Tp at a modeling density comparable to that in FIG. 13. FIG. 17 shows an infill path IP10 and an infill path IP11 for modeling the infill area IAm of the layer ML at a modeling density comparable to that in FIG. 14. The infill path IP7 is the first zigzag path, and the infill paths IP8 to IP11 are the second zigzag path.

As in the examples in FIGS. 15 to 17, when paths are generated for the entire undivided infill area, a path length of the partial paths generated as the infill path tends to be longer than that in the embodiment. For example, in the example in FIG. 15, a plurality of partial paths extending from one end to the other end of the infill area IA1 in the X direction are generated, and in the examples in FIGS. 16 and 17, a plurality of partial paths extending from one end to the other end of the infill area IAt or the infill area IAm in the Y direction are generated. On the other hand, in the embodiment, the infill area is divided into a plurality of divided areas such that the movement path satisfying the path length condition is generated in each of the divided areas, then the movement path is generated in each of the divided areas, and thus an increase in the path length of the partial path can be prevented. Therefore, by modeling the three-dimensional object OB according to the modeling data generated as described above, the possibility of preventing warpage of a three-dimensional object increases regardless of whether a filler is contained in the material for modeling.

In the embodiment, the infill path data is generated such that the direction of the path pattern is different between the first divided area PA1a and the second divided area PA1b that are adjacent to each other. Therefore, for example, in the first divided area PA1a and the second divided area PA1b, compared to a case where the movement path is generated using the path patterns having the same direction, the possibility of preventing the warpage of the three-dimensional object further increases.

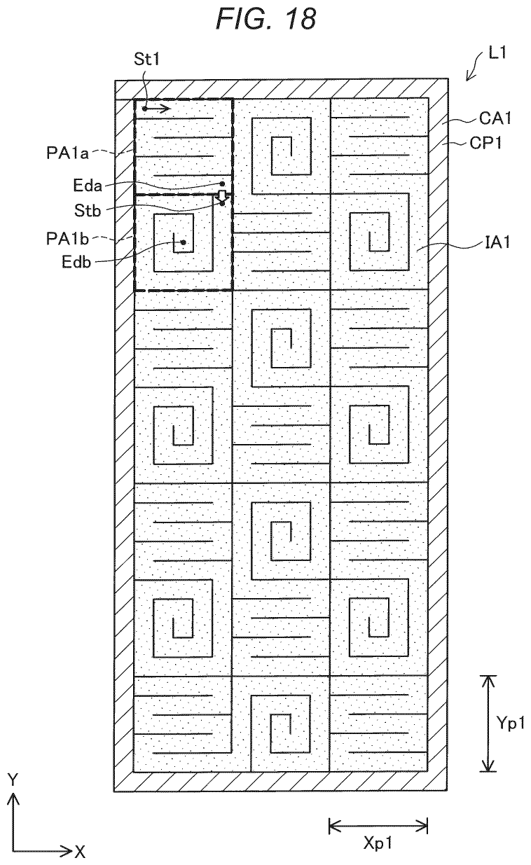

FIG. 18 is a diagram showing a state in which movement paths are generated in divided areas in step S135 in another embodiment. FIG. 18 shows a state in which movement paths are generated in the infill area IA1 of the layer L1, in substantially the same manner as in FIG. 10. In the example in FIG. 18, unlike the embodiment, infill path data is generated such that a shape of a path pattern is different between the first divided area PA1a and the second divided area PA1b. More specifically, the first zigzag path is generated in the first divided area PA1a as in FIG. 10, and a vortex path, which is a movement path in a vortex shape, is generated in the second divided area PA1b unlike in FIG. 10. The vortex path refers to a movement path extending in a vortex shape from the outer periphery toward the center, or from the center toward the outer periphery, within the area where the vortex path is to be generated. As described above, by generating the infill path data such that the shape of the path pattern is different between the first divided area PA1a and the second divided area PA1b, the possibility of preventing the warpage of the three-dimensional object further increases.

In the embodiment, the zigzag path that is folded back in the X direction is generated in the first divided area PA1a, and the zigzag path that is folded back in the Y direction is generated in the second divided area PA1b. Therefore, by generating a path of a simple pattern in the first divided area PA1a and the second divided area PA1b, the warpage of the three-dimensional object can be effectively prevented.

In the embodiment, the infill areas of the first layer and the second layer are divided such that the division boundary Br1 and the division boundary Br2 are shifted from each other between the first layer and the second layer provided in the lower layer area LA when viewed in the depositing direction. Therefore, the strength of the lower layer area LA can be further increased, and the strength of the three-dimensional object can be further increased. In another embodiment, the infill areas of the first layer and the second layer may be divided such that the division boundaries of the first layer and the second layer provided in the upper layer area UA are shifted from each other. In this case, the strength of the upper layer area UA can be increased. By shifting the division boundary between the first layer and the second layer in this manner, the shape of the middle layer area MA can be prevented from being visually recognized from the outside of the three-dimensional object through the division boundary, and thus an aesthetic appearance of the three-dimensional object can be further improved. For example, both the lower layer area LA and the upper layer area UA may include layers corresponding to the first layer and the second layer. That is, in both the lower layer area LA and the upper layer area UA, the infill area may be divided such that the division boundaries of two layers continuous in the depositing direction are shifted from each other. For example, the middle layer area MA may include layers corresponding to the first layer and the second layer.

In the embodiment, the infill path data is generated so as to connect the ends of the movement paths in the two adjacent divided areas PA. Therefore, the three-dimensional object can be more efficiently modeled.

### B. Other Embodiments

(B-1) In the above embodiments, the first acquisition unit 412 acquires the slice data by generating the slice data based on the shape data, but it is not necessary to acquire slice data in this way. For example, the first acquisition unit 412 may acquire slice data related to an object desired to be modeled from another computer, a recording medium, or the storage unit 430.

(B-2) In the above embodiments, in the second generation step, the infill path data is generated such that at least one of the shape and the direction of the path pattern is different between the first divided area PA1a and the second divided area PA1b. On the other hand, the movement path may be generated using a path pattern having the same shape and direction in the first divided area PA1a and the second divided area PA1b.

(B-3) In the above embodiments, for example, the infill path may be generated by using path patterns having different shapes and directions in the first layer and the second layer provided in the upper layer area UA and the lower layer area LA. In this way, the shape of the middle layer area MA can be prevented from being visually recognized from the outside of the three-dimensional object through the gap due to the gap between the linear plasticized materials extruded along the respective partial paths in the first layer and the second layer being shifted. For example, by generating the infill path in one layer provided in the lower layer area LA in the same manner as in FIG. 10 and generating the infill path in another layer provided in the lower layer area LA in the same manner as in FIG. 15, the gaps between the plasticized materials can be shifted, and the shape of the middle layer area MA can be prevented from being visually recognized from the outside of the three-dimensional object through the gaps. For example, by generating the infill path in one layer provided in the upper layer area UA in the same manner as in FIG. 13 and generating the infill path in another layer provided in the upper layer area UA in the same manner as in FIG. 16, similarly, the shape of the middle layer area MA can be prevented from being visually recognized from the outside of the three-dimensional object.

(B-4) In the above embodiments, in at least one of the upper layer area UA and the lower layer area LA, the infill areas of the first layer and the second layer are divided such that the division boundaries of the first layer and the second layer that are continuous in the depositing direction are shifted from each other. On the other hand, the infill areas of the first layer and the second layer may not be divided such that the division boundaries between the first layer and the second layer are shifted from each other. In the above embodiments, the middle layer area MA is modeled at a modeling density lower than that of the lower layer area LA and the upper layer area UA, but the middle layer area MA may be modeled at a modeling density same as that of the lower layer area LA and the upper layer area UA, or the middle layer area MA may be modeled at a modeling density higher than that of the lower layer area LA and the upper layer area UA.

(B-5) In the above embodiments, in the second generation step, the infill path data is generated so as to connect the ends of the paths in the two adjacent divided areas. On the other hand, in the second generation step, the ends of the movement paths in the two adjacent divided areas may not be coupled to each other.

(B-6) In the above embodiments, the plasticizing unit 30 plasticizes the material with the flat screw. On the other hand, the plasticizing unit 30 may plasticize the material by rotating an in-line screw, for example. The plasticizing unit 30 may plasticize a filament material with a heater.

(B-7) In the above embodiments, the path condition may include, for example, a condition other than the condition shown in FIG. 8. The path condition may not include, for example, a pattern condition or a density condition. In this case, the path pattern and the modeling density may be determined regardless of a material type. In this case, for example, the data generation unit 415 may receive designation of a path pattern or a modeling density from the user via the input device 470. In the above embodiments, each of the divided areas is a rectangular area having the same area, but when the movement path satisfying the path length condition can be generated within each of the divided areas, it is not necessary to use such an area. For example, the divided areas may have different areas from each other, or the divided areas may have other polygonal shapes such as a triangular shape or a five-sided shape instead of the rectangular shape.

(B-8) In the above embodiments, a resin material formed into pellets is used as the raw material supplied to the material supply unit 20. The three-dimensional modeling apparatus 100 can model a three-dimensional object using various materials. For example, the three-dimensional modeling apparatus 100 can model a three-dimensional object by using various thermoplastic materials as a main material. Here, the “main material” means a material serving as a center forming the shape of the three-dimensional object, and means a material having a content of 50% by weight or more in the three-dimensional object. The above-described plasticized material includes those obtained by melting the main material alone, and those obtained by melting some or all of the components contained together with the main material into a paste form. In addition to a pigment, a metal, and a ceramic, additives such as a wax, a flame retardant, an antioxidant, and a heat stabilizer may be mixed into the thermoplastic material.

As the thermoplastic material, for example, the following thermoplastic resin material can be used.

### Examples of Thermoplastic Resin Material

Polypropylene resin (PP), polyethylene resin (PE), polyacetal resin (POM), polyvinyl chloride resin (PVC), polyamide resin (PA), acrylonitrile-butadiene-styrene resin (ABS), polylactic acid resin (PLA), polyphenylene sulfide resin (PPS), polyether ether ketone (PEEK), polycarbonate (PC), general-purpose engineering plastics such as modified polyphenylene ether, polybutylene terephthalate, and polyethylene terephthalate, and engineering plastics such as polysulfone, polyethersulfone, polyphenylene sulfide, polyarylate, polyimide, polyamideimide, polyetherimide, and polyetheretherketone.

### C. Other Embodiments

The present disclosure is not limited to the above embodiments, and can be implemented in various forms without departing from the spirit of the present disclosure. For example, the present disclosure can be implemented in the following aspects. In order to solve a part of or all of problems of the present disclosure, or to achieve a part of or all of effects of the present disclosure, technical features of the above-described embodiments corresponding to technical features in each of the following aspects can be replaced or combined as appropriate. Technical characteristics can be deleted as appropriate unless described as essential in the present specification.

(1) According to a first aspect of the present disclosure, there is provided a method for generating three-dimensional modeling data for modeling a three-dimensional object by depositing a layer of a plasticized material. The method for generating three-dimensional modeling data includes: an acquiring step of acquiring slice data representing a shape of the three-dimensional object sliced into a plurality of layers; an acquiring step of acquiring material information on a material used for modeling the three-dimensional object; an acquiring step of acquiring, based the material information, a path condition predetermined according to a material type; and a data generation step of generating, based on the slice data, path data in which a movement path along which a nozzle moves while extruding the plasticized material is represented by a plurality of partial paths. The path data includes contour path data for modeling a contour area including a contour of the three-dimensional object and infill path data for modeling an infill area which is an inner area of the contour area, and the path condition includes a path length condition related to an upper limit of a length of the partial path in the infill area. The data generation step includes a first generation step of generating the contour path data by generating the movement path in the contour area, and a second generation step of generating the infill path data by dividing the infill area into a plurality of divided areas and generating the movement path in each of the divided areas according to a predetermined path pattern. In the second generation step, the infill area is divided such that the movement path satisfying the path length condition is generated in each of the divided areas.

According to this aspect, the infill area is divided into the plurality of divided areas such that the movement path satisfying the path length condition is generated within each of the divided areas, and then the movement path can be generated in each of the divided areas. Therefore, for example, compared to a case where the movement path is generated in the infill area without dividing the infill area, an increase in a path length of the partial path can be prevented. Accordingly, the possibility of preventing warpage of the three-dimensional object increases regardless of whether a filler is contained in the material for modeling.

(2) In the above aspect, the plurality of divided areas may include a first divided area and a second divided area adjacent to the first divided area, and in the second generation step, the infill path data may be generated such that at least one of a shape and a direction of the path pattern is different between the first divided area and the second divided area. According to this aspect, the movement path can be generated using the path patterns having different shapes and directions in the divided areas adjacent to each other, and thus the possibility of preventing the warpage of the three-dimensional object increases.

(3) In the above aspect, in the second generation step, the movement path of a zigzag shape that folds back in a first direction may be generated in the first divided area, and the movement path of a zigzag shape that folds back in a second direction intersecting the first direction may be generated in the second divided area. According to this aspect, the warpage of the three-dimensional object can be effectively prevented by the simple path pattern.

(4) In the above aspect, the path data may include lower layer data for modeling a lower layer area including a lowermost layer of the three-dimensional object, upper layer data for modeling an upper layer area including an uppermost layer of the three-dimensional object, and middle layer data for modeling a middle layer area between the lower layer area and the upper layer area at a density lower than that of the lower layer area and the upper layer area, the upper layer data, the middle layer data, and the lower layer data may each include the contour path data and the infill path data, at least one of the lower layer area and the upper layer area may include a first layer and a second layer continuous with the first layer in a depositing direction, and in the second generation step, the infill areas of the first layer and the second layer may be divided such that a boundary of the divided area in the first layer and the boundary in the second layer are shifted when viewed in the depositing direction. According to this aspect, the strength of the lower layer area and the upper layer area can be further increased, and the strength of the three-dimensional object can be further increased.

(5) In the above aspect, in the second generation step, the infill path data may be generated such that ends of the movement paths in two adjacent divided areas are coupled to each other. According to this aspect, a three-dimensional object can be more efficiently modeled.

(6) According to a second aspect of the present disclosure, there is provided an information processing apparatus for generating three-dimensional modeling data for modeling a three-dimensional object by depositing a layer of a plasticized material. The information processing apparatus includes: a first acquisition unit configured to acquire slice data representing a shape of the three-dimensional object sliced into a plurality of layers; a second acquisition unit configured to acquire material information on a material used for modeling the three-dimensional object; a third acquisition unit configured to acquire, based on the material information, a path condition predetermined according to a material type; and a data generation unit configured to generate, based on the slice data, path data in which a movement path along which a nozzle moves while extruding the plasticized material is represented by a plurality of partial paths. The path data includes contour path data for modeling a contour area including a contour of the three-dimensional object and infill path data for modeling an infill area which is an inner area of the contour area, and the path condition includes a path length condition related to an upper limit of a length of the partial path in the infill area. The data generation unit executes first generation processing of generating the contour path data by generating the movement path in the contour area, and second generation processing of generating the infill path data by dividing the infill area into a plurality of divided areas and generating the movement path in each of the divided areas according to a predetermined path pattern. In the second generation processing, the infill area is divided such that the movement path satisfying the path length condition is generated in each of the divided areas.

What is claimed is:

1. A method for generating three-dimensional modeling data for modeling a three-dimensional object by depositing a layer of a plasticized material, the method comprising:
an acquiring step of acquiring slice data representing a shape of the three-dimensional object sliced into a plurality of layers;
an acquiring step of acquiring material information on a material used for modeling the three-dimensional object;
an acquiring step of acquiring, based on the material information, a path condition predetermined according to a material type; and
a data generation step of generating, based on the slice data, path data in which a movement path along which a nozzle moves while extruding the plasticized material is represented by a plurality of partial paths, wherein
the path data includes contour path data for modeling a contour area including a contour of the three-dimensional object and infill path data for modeling an infill area which is an inner area of the contour area,
the path condition includes a path length condition related to an upper limit of a length of the partial path in the infill area,
the data generation step includes
a first generation step of generating the contour path data by generating the movement path in the contour area, and
second generation step of generating the infill path data by dividing the infill area into a plurality of divided areas and generating the movement path in each of the divided areas according to a predetermined path pattern, and
in the second generation step, the infill area is divided such that the movement path satisfying the path length condition is generated in each of the divided areas.

2. The method for generating three-dimensional modeling data according to claim 1, wherein
the plurality of divided areas include a first divided area and a second divided area adjacent to the first divided area, and
in the second generation step, the infill path data is generated such that at least one of a shape and a direction of the path pattern is different between the first divided area and the second divided area.

3. The method for generating three-dimensional modeling data according to claim 2, wherein
in the second generation step, the movement path of a zigzag shape that folds back in a first direction is generated in the first divided area, and the movement path of a zigzag shape that folds back in a second direction intersecting the first direction is generated in the second divided area.

4. The method for generating three-dimensional modeling data according to claim 1, wherein
the path data includes lower layer data for modeling a lower layer area including a lowermost layer of the three-dimensional object, upper layer data for modeling an upper layer area including an uppermost layer of the three-dimensional object, and middle layer data for modeling a middle layer area between the lower layer area and the upper layer area at a density lower than that of the lower layer area and the upper layer area,
the upper layer data, the middle layer data, and the lower layer data each include the contour path data and the infill path data,
at least one of the lower layer area and the upper layer area includes a first layer and a second layer continuous with the first layer in a depositing direction, and
in the second generation step, the infill areas of the first layer and the second layer are divided such that a boundary of the divided area in the first layer and the boundary in the second layer are shifted when viewed in the depositing direction.

5. The method for generating three-dimensional modeling data according to claim 1, wherein
in the second generation step, the infill path data is generated such that ends of the movement paths in two adjacent divided areas are coupled to each other.
